(19) United States
(12) Patent Application Publication
(10) Pub. No.: US 2025/0276858 A1
(43) Pub. Date: Sep. 4, 2025

(54) END EFFECTOR AND SUBSTRATE PROCESSING SYSTEM USING THE SAME

(71) Applicant: ASM IP Holding B.V., Almere (NL)

(72) Inventors: Kenji Mizusawa, Tokyo (JP); Yuki Dammura, Yamato-shi (JP); Masaei Suwada, Nagaoka-shi (JP)

(21) Appl. No.: 19/064,376

(22) Filed: Feb. 26, 2025

Related U.S. Application Data
(60) Provisional application No. 63/559,827, filed on Feb. 29, 2024.

(51) Int. Cl. B65G 47/90

(52) U.S. Cl. CPC B65G 47/90

(57) ABSTRACT

An end effector used for transporting a substrate in a substrate processing system is presented. The end effector comprises a paddle configured to support a substrate and the paddle being flat; a blade part connected to the paddle at a first end of the paddle, wherein a distal end of the blade part is provided with a front protrusion for positioning a substrate; and a plurality of pads disposed in each of a plurality of holes, wherein the plurality of pads contact the substrate when transporting the substrate and wherein the plurality of holes are disposed in the paddle and the blade part. The end effectors may allow tilting of the pads so that substrates would not stick.

### CROSS-REFERENCE TO RELATED APPLICATION(S)

This application claims the benefit of U.S. Provisional Application 63/559,827 filed on Feb. 29, 2024, the entire contents of which are incorporated herein by reference.

### FIELD OF INVENTION

The present disclosure relates generally to an end effector. More particularly, exemplary embodiments of the present disclosure relate to an end effector for transporting a substrate and a substrate processing apparatus including the end effector.

### BACKGROUND OF THE DISCLOSURE

The pads in backside contact type end effectors currently used in robots (attached to robot arms) in substrate processing systems may suffer from a) substrates sticking and b) wearing out when used long. The lifetime of the pad is relatively short (i.e., usually 6 months or so) so when maintenance is not done in time, the substrate contact region at the top part of the pad would be worn out.

Also, when handling a silicon substrate with a robot, the substrate may bounce on the pad of the end effector, or the substrate may be misaligned due to contact imbalance. Therefore, the present disclosure presents a new end effector structure with capabilities to absorb shocks and to correct tilting of the pad automatically for preventing substrates from bouncing and improving the substrate's state of contact area.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with one embodiment there may be provided, an end effector used in transporting a substrate, comprises: a paddle configured to support a substrate and the paddle being flat; a blade part connected to the paddle at a first end of the paddle, wherein a distal end of the blade part is provided with a front protrusion for positioning a substrate; and a plurality of pads disposed in each of a plurality of holes, wherein the plurality of pads contact the substrate when transporting the substrate and wherein the plurality of holes are disposed in the paddle and the blade part.

In an aspect, the end effector further comprises a joint section connected to the paddle at a second end of the paddle and configured to be attached to a robotic arm.

In an aspect, a number of the holes is equal to or greater than three.

In an aspect, the blade part comprises at least one blade.

In an aspect, each of the plurality of pads comprises: a supporting unit configured to support the substrate on its top side when transporting the substrate; and an absorbing unit configured to encircle a lower side of the supporting unit and fitted into a hole, wherein the absorbing unit is elastic and flexible to be able to absorb shocks and seal the supporting unit and the hole.

In an aspect, the absorbing unit is an O-ring; and an inner side of the hole has a concave shape, wherein the O-ring is configured to fit into the concave shape of the inner side of the hole.

In an aspect, the absorbing unit has a concave shape around its side and an inner side of the hole has a protrusion; and the protrusion of the inner side of the hole is configured to fit into the concave shape of the absorbing unit.

In an aspect, the supporting unit is configured to tilt to a certain degree in the same direction as a direction of the substrate movement when the substrate slides.

In an aspect, the supporting unit is configured to have a round top shape.

In an aspect, the supporting unit is made of ceramics, and the absorbing unit is made of elastomer.

In accordance with another embodiment there may be provided, a backend robot for transporting a substrate, comprises: a robotic arm comprising at least two arm parts, the robotic arm configured to move a substrate from one place to another place; and an end effector connected to the robotic arm, and configured to move the substrate placed on the end effector, wherein the end effector is as described above.

In accordance with another embodiment there may be provided, a substrate processing apparatus comprising: a reaction chamber for processing a substrate; a substrate handling chamber attached to the reaction chamber; a backend robot disposed in the substrate handling chamber and the backend robot comprises a robotic arm and an end effector attached to the robotic arm; and a load lock chamber attached to the substrate handling chamber and configured to load or unload the substrate, wherein the end effector is as described above.

### BRIEF DESCRIPTION OF THE DRAWING FIGURES

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

FIG. 1 illustrates a view of a substrate processing system with a robot equipped with an end effector according to an embodiment of the present disclosure.

FIG. 2 illustrates a separate, isolated view of a robot (with robotic arm and end effector) according to an embodiment of the present disclosure.

FIG. 3(a) illustrates a mode of an end effector (4 pads) according to an embodiment of the present disclosure.

FIG. 3(b) illustrates a different mode of an end effector (3 pads) according to another embodiment of the present disclosure.

FIG. 4(a) illustrates a side and separate view of the end effector's supporting unit and absorbing unit as well as a hole in a paddle or in a blade according to an embodiment of the present disclosure.

FIG. 4(b) illustrates a side view of the end effector's supporting unit placed in a hole and supporting a substrate according to an embodiment of the present disclosure.

FIG. 4(c) illustrates a side view of the end effector's supporting unit tilted by a substrate's movement according to an embodiment of the present disclosure.

FIG. 5(a) illustrates a perspective view of end effector's supporting unit and absorbing unit according to an embodiment of the present disclosure.

FIG. 5(b) illustrates a front view of the end effector's supporting unit tilted by the substrate's movement according to another embodiment of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

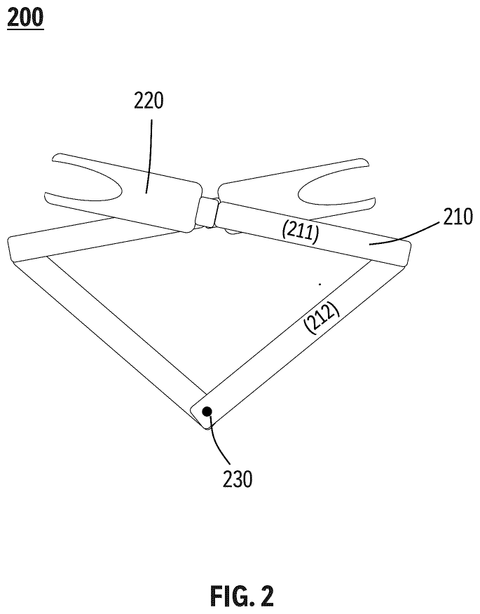

FIG. 2 illustrates a separate view of a robot usually used in a substrate processing system.

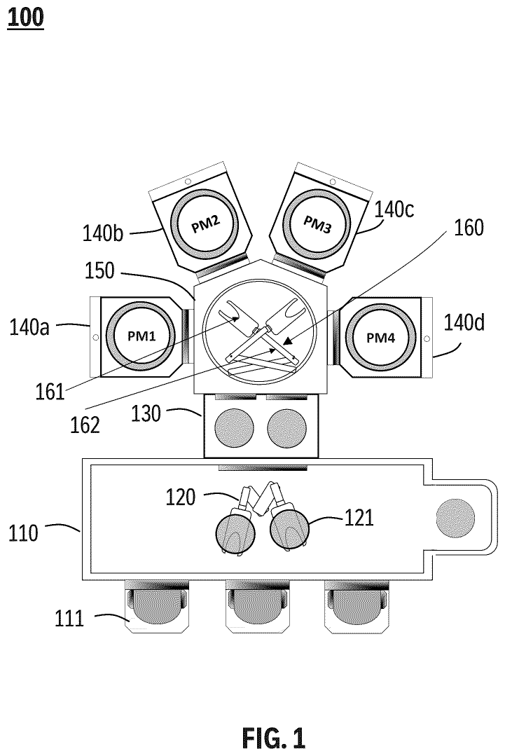

A robot 200 may comprise a robotic arm 210 and an end effector 220 attached to it. The robotic arm 210 may comprise an upper arm part 211 which is connected to the end effector 220 and a lower arm part 212 which is attached to an axis 230. The robot 200 has a robotic arm which comprises 2 pieces of arm parts (outer arm part 211 and inner arm part 212) in FIG. 1, however there are other applications which use 3 or more pieces of arm parts and FIG. 1 is only one example and the outer arm part 211 may be connected to an end effector 220. The shape of each of the arm part may be varied in accordance with characteristics of the processing system's requirements and environments.

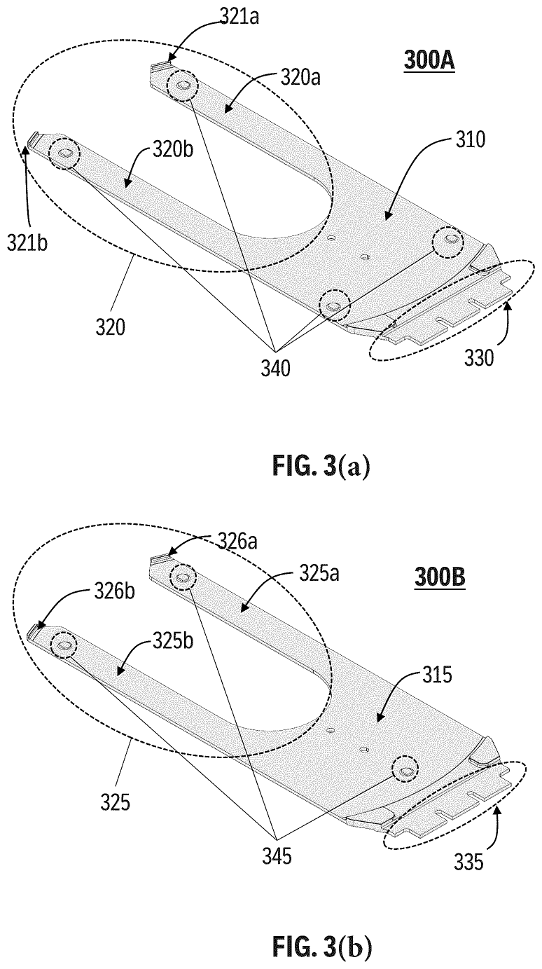

For a backside contact type end effector, the end effector 220 may have several pads. FIGS. 3(a) and 3(b) illustrate two different modes of end effectors such as 4 pads and 3 pads respectively according to embodiments of the present disclosure.

In FIG. 3(a), an end effector 300A may comprise a paddle 310, a blade part 320, and a plurality of pads 340. Each of the pads 340 may be disposed in a hole (not shown in FIG. 3(a)). The paddle 310 may be flat for supporting a substrate and the paddle 310 may also be used to position a substrate in its right position.

The blade part 320 may be connected to the paddle 310 at one end direction. At the end of the blade part 320 at the opposite side (distal end), a front protrusion (321a, 321b) may be provided for positioning a substrate on the end effector 300A. By the protrusion (321a, 321b), a substrate placed on the end effector 300A may find a right place to stay while it is transported by the end effector 300A. A joint section 330 may be connected to the paddle 310 at a second end of the paddle 310 and configured to be attached to a robotic arm (shown later).

The pads 340 may be placed anywhere in the paddle 310 and the blade part 320 altogether for placing a substrate on the end effector 300A. There may be a hole (will be shown below) for placing a pad 340 so there may be equal numbers of holes and pads in an end effector. The pads 340 may be positioned symmetrically so that a substrate placed on an end effector may contact the pads 340 and the substrate may remain in stable state. In FIG. 3(a), the four pads 340 may form a rectangular shape for symmetry and substrate stability for an example.

The blade part 320 may have at least one blades. In FIG. 3(a), the blade part 320 may comprise 2 blades 320a, 320b for an example. If there may be more than one blades, then each blade (320a, 320b) may have its own front protrusions (321a, 321b).

The holes (i.e., the pads) may be placed in the paddle 310 and in the blade part 320 and the number of the holes (i.e., the pads) may be more than three for supporting a substrate placed on the pads 340 stable.

In FIG. 3(b), an end effector 300B may comprise a paddle 315, a blade part 325, and a plurality of pads 345. Each of the pads 345 may be disposed in a hole (not shown in FIG. 3(b)). The paddle 315 may be flat for supporting a substrate and the paddle 315 may also be used to position a substrate in its right position.

The blade part 325 may be connected to the paddle 315 at one end direction. At the end of the blade part 325 at the opposite side (distal end), a front protrusion (326a, 326b) may be provided for positioning a substrate on the end effector 300B. By the protrusion (326a, 326b), a substrate placed on the end effector 300B may find a right place to stay while it is transported by the end effector 300B. A joint section 335 may be connected to the paddle 315 at a second end of the paddle 315 and configured to be attached to a robotic arm (shown later).

The pads 345 may be placed anywhere in the paddle 315 and the blade part 325 altogether for placing a substrate on the end effector 300B. There may be a hole (will be shown below) for placing a pad 345 so there may be equal numbers of holes and pads in an end effector. The pads 345 may be positioned symmetrically so that a substrate placed on an end effector may contact the pads 345 and the substrate may remain in stable state. In FIG. 3(b), the three pads 345 may form a triangular shape for symmetry and substrate stability for an example.

The blade part 325 may have at least one blades. In FIG. 3(b), the blade part 325 may comprise 2 blades 325a, 325b for an example. If there may be more than one blades, then each blade (325a, 325b) may have its own front protrusions (326a, 326b).

The holes (i.e., the pads) may be placed in the paddle 315 and in the blade part 325 and the number of the holes (i.e., the pads) may be more than three for supporting a substrate placed on the pads 345 stable.

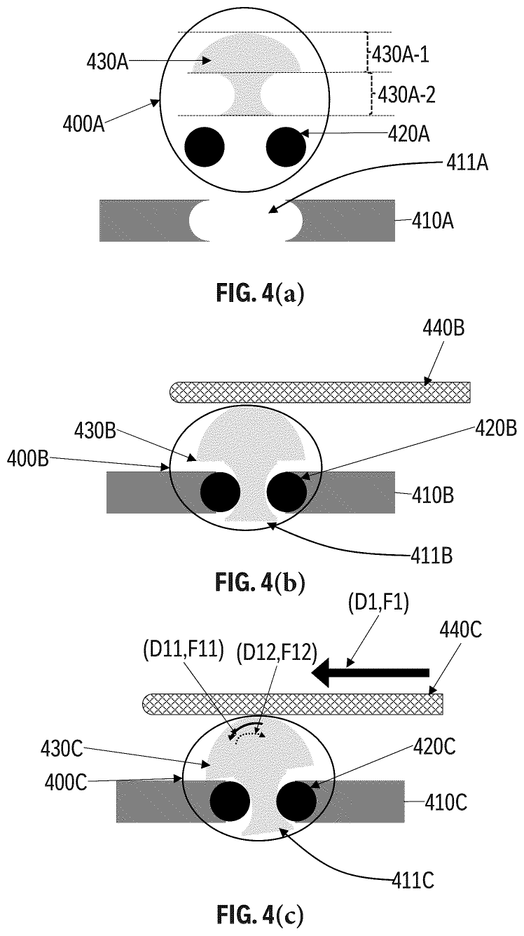

FIGS. 4(a)-(c) illustrate one mode of pad used in end effectors according to one embodiment of the present disclosure.

As illustrated in FIG. 4(a), a pad 400A may comprise a supporting unit 430A and an absorbing unit 420A. The supporting unit 430A may support a substrate on its top side 430A-1 when the substrate may be placed on the pad 400A and transported to another region. To prevent any damages (scratches for example) to the substrate placed on the pad 400A and also to prevent particle problem caused by large contact (substrate-pad contact) region, the top side 430A-1 of the pad 400A may be shaped round as shown in FIG. 4(a). For the reasons stated above, the supporting unit 430A or at least the top side 430A-1 may be made of ceramics.

The absorbing unit 420A may encircle a lower side 430A-2 of the supporting unit 430A. For sealing effect, the absorbing unit 420A may be elastic to encircle the supporting unit 430A tightly.

For an example, the absorbing unit 420A may be an O-ring. In this case, for a hole 411A in an end effector 410A, the shape of inner side of the hole is concave-shaped. That way, the O-ring (absorbing unit 420A) may fit into the inner side of the hole 411A. This embodiment may be shown in FIG. 4(b).

In FIG. 4(b), a pad 400B may be fitted into a hole 411B on an end effector 410B (in paddle or in blade part) and a substrate 440B may be placed on the pad 400B. The supporting unit 430B may support the substrate 440B with its round top side and its absorbing unit 420B may tightly encircle lower side of the supporting unit 430B and the absorbing unit 420B also may be fitted into the hole 411B. The sectional shape of the absorbing unit 420B may be anything however a circular shape (just like an O-ring) is shown for an efficiency example.

When the substrate 440C may move on the end effector 410C with a direction (D1) and force (F1), the pad 400C, more specifically the supporting unit 430C, may move along with the substrate 440C with a direction (D11) and force (F11) whose direction (D11) is somewhat almost the same with the substrate 440C's direction (D1) but the force of the movement (D11) may be much lessened compared to the substrate's movement force (F1) because the absorbing unit 420C may tightly grab supporting unit 430C. The supporting unit 430C may be tilted somewhat until a certain degree.

This kind of substrate's movement (D1, F1) may mean a misplacement of the substrate 440C. Therefore, the original position may be a right position (or at least closer to a right or aligned position) so restoring the substrate 440C to its original position would be better when transporting it. By the elasticity of the absorbing unit 420C, the tilted supporting unit 430C may be reversed its movement with a direction (D12) and a force (F12). The direction (D12) would be the opposite to the direction (D1) but the force (F12) may be a lot smaller than the force (F1). And this kind of tilting (D11, F11) and un-tilting (D12, F12) movements may be beneficial such that the contact regions of the substrate 440C and the supporting unit 430C may change during the tilting and un-tilting movements so substrate sticking problem (a problem that a substrate is sticking to a pad so that the substrate would not move when it is needed) may be solved too.

To show a good example, the absorbing unit 420A may be an O-ring (with circular sectional shape) and the shape of the lower side 430A-2 of the supporting unit 430A where the absorbing unit 420A encircles may be concave to be fitted into the absorbing unit 420A (i.e., O-ring). Also, the shape of the end effector's hole 411A may be a concave to be fitted into the absorbing unit 420B, 420C just like FIG. 4(b) and FIG. 4(c).

For a tight sealing effect and an elastic movement effect (tilting and un-tilting of the supporting unit), the absorbing unit 420C may be made of elastomer or any material with elasticity and high resistance to high temperature.

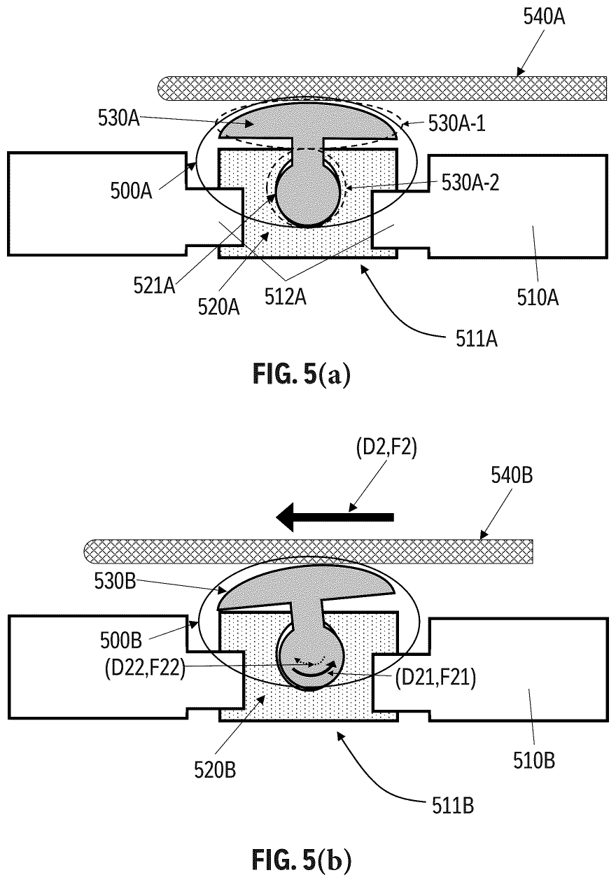

FIG. 5(a) and FIG. 5(b) illustrate another mode of embodiment according to the present disclosure.

In FIG. 5(a), a pad 500A may be fitted into a hole 511A on an end effector 510A (in paddle or in blade part) and a substrate 540A may be placed on the pad 500A. The supporting unit 530A may support the substrate 540A with its round top side and its absorbing unit 520A may tightly encircle lower side of the supporting unit 530A and the absorbing unit 520A also may be fitted into the hole 511A. The sectional shape of the absorbing unit 520A may be anything however a rectangular shape is shown for another example. In this mode, the absorbing unit 520A may have a concave shape around its side and an inner side of the hole has a protrusion 512A. The protrusion 512A of the inner side of the hole 511A may be fitted into the concave shape of the absorbing unit 520A.

When the substrate 540B may move on the end effector 510B with a direction (D2) and force (F2), the pad 500B, more specifically the supporting unit 530B, may move with a direction and force (D21, F21) whose direction (D21) is somewhat almost the opposite to the substrate 540B's direction (D2) but the force of the movement (D21) may be much lessened compared to the substrate's movement force (F2) because the absorbing unit 520B may tightly grab supporting unit 530B. The supporting unit 530B may be tilted somewhat until a certain degree.

This kind of substrate's movement (D2, F2) may mean a misplacement of the substrate 540B. Therefore, the original position may be a right position (or at least closer to a right or well-aligned position) so restoring the substrate 540B to its original position would be better when transporting it. By the elasticity of the absorbing unit 520B, the tilted supporting unit 530B may be reversed its movement with a direction and a force (D22, F22). The direction (D22) would be almost the same to the direction (D2) but the force (F22) may be a lot smaller than the force (F2). This reversed un-tilting movement of the supporting unit 530B may be resulted from the supporting unit 530B and absorbing unit 520B's combined structure. And the tilting (D21, F21) and un-tilting (D22, F22) movements may be beneficial such that the contact regions of the substrate 540B and the supporting unit 530B may change during the tilting and un-tilting movements so substrate sticking problem (a problem that a substrate is sticking to a pad so that the substrate would not move when it is needed) may be solved too.

For an example, the absorbing unit 520A may be a block of elastic material (with rectangular sectional shape) and the shape of the lower part 530A-2 of the supporting unit 530A where the absorbing unit 520A encircles may be concave to be fitted into the absorbing unit 520A's dent 521A. Also, the shape of the inside of the end effector's hole 511A may have a protrusion to be fitted into the side of absorbing unit 520A just like FIG. 5(a) and FIG. 5(b). In this mode of embodiment, the sealing ability of the absorbing unit 520A (into the hole 511A) may be almost perfect.

For a tight sealing effect, an elastic movement effect (tilting and un-tilting of the supporting unit), and solving the substrate sticking problem, the absorbing unit 520B may be made of elastomer or any material with elasticity and high resistance to high temperature.

FIG. 1 is a schematic plan view of a substrate processing system using a robot equipped with an end effector according to an embodiment of the present disclosure. The system 100 comprise a reaction chamber 140a˜ 140d, a substrate handling chamber 150, a backend robot 160 disposed in the substrate handling chamber 150 and the backend robot 160 comprises a robotic arm 162 and an end effector 161 attached to the robotic arm 162. The system 100 also comprises a load lock chamber 130 next to the substrate handling chamber 150 and configured to load or unload the substrate. The end effector 161 in this system 100 is one of the modes explained in this disclosure.

The above-described arrangements of apparatus are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. An end effector used for transporting a substrate, comprises:
a paddle configured to support a substrate and the paddle being flat;
a blade part connected to the paddle at a first end of the paddle, wherein a distal end of the blade part is provided with a front protrusion for positioning the substrate; and
a plurality of pads disposed in each of a plurality of holes, wherein the plurality of pads contact the substrate when transporting the substrate and wherein the plurality of holes are disposed in the paddle and the blade part.

2. An end effector according to the claim 1, further comprises:
a joint section connected to the paddle at a second end of the paddle and configured to be attached to a robotic arm.

3. An end effector according to claim 2, wherein a number of the holes is equal to or greater than three (3).

4. An end effector according to the claim 2, wherein the blade part comprises at least one blade.

5. An end effector according to the claim 2, wherein each of the plurality of pads comprises:
a supporting unit configured to support the substrate on its top side when transporting the substrate; and
an absorbing unit configured to encircle a lower side of the supporting unit and fitted into a hole,
wherein the absorbing unit is elastic and flexible to be able to absorb shocks and seal the supporting unit and the hole.

6. An end effector according to the claim 5, wherein the absorbing unit is an O-ring; and an inner side of the hole has a concave shape, wherein the O-ring is configured to fit into the concave shape of the inner side of the hole.

7. An end effector according to the claim 5, wherein the absorbing unit has a concave shape around its side and an inner side of the hole has a protrusion; and
the protrusion of the inner side of the hole is configured to fit into a concave shape of the absorbing unit.

8. An end effector according to claim 6, wherein the supporting unit is configured to tilt to a certain degree in a same direction as a direction of a substrate movement when the substrate slides.

9. An end effector according to the claim 5, wherein the supporting unit is configured to have a round top shape.

10. An end effector according to the claim 5, wherein the supporting unit is made of ceramics, and the absorbing unit is made of elastomer.

11. A backend robot for transporting a substrate, comprises:
a robotic arm comprising at least two arm parts, the robotic arm configured to move a substrate from one place to another place; and
an end effector connected to the robotic arm, and configured to move the substrate placed on the end effector, wherein the end effector comprises:
a paddle configured to support the substrate and the paddle being flat;
a blade part connected to the paddle at a first end of the paddle, wherein a distal end of the blade part is provided with a front protrusion for positioning the substrate; and
a plurality of pads disposed in each of a plurality of holes, wherein the plurality of pads contact the substrate when transporting the substrate and wherein the plurality of holes are disposed in the paddle and the blade part.

12. A substrate processing apparatus comprising:
a reaction chamber for processing a substrate;
a substrate handling chamber attached to the reaction chamber;
a backend robot disposed in the substrate handling chamber and the backend robot comprises a robotic arm and an end effector attached to the robotic arm; and
a load lock chamber attached to the substrate handling chamber and configured to load or unload the substrate, wherein the end effector comprises:
a paddle configured to support the substrate and the paddle being flat;
a blade part connected to the paddle at a first end of the paddle, wherein a distal end of the blade part is provided with a front protrusion for positioning the substrate; and
a plurality of pads disposed in each of a plurality of holes, wherein the plurality of pads contact the substrate when transporting the substrate and wherein the plurality of holes are disposed in the paddle and the blade part.
